(19) United States
(12) Patent Application Publication
(10) Pub. No.: US 2026/0050015 A1
(43) Pub. Date: Feb. 19, 2026

(54) CO-LOCATED DIFFERENTIAL MAGNETIC SENSOR CLUSTERS FOR SAFETY REDUNDANCY

(71) Applicant: Allegro MicroSystems, LLC, Manchester, NH (US)

(72) Inventors: Matthew Hein, Dallas, TX (US); Robert A. Briano, Auburn, NH (US); Juan Manuel Cesaretti, Buenos Aires (AR); Rostislav Doganov, Schwetzingen (DE); Maxwell McNally, Manchester, NH (US); Václav Mach, Praha (CZ)

(73) Assignee: Allegro MicroSystems, LLC, Manchester, NH (US)

(21) Appl. No.: 18/808,279

(22) Filed: Aug. 19, 2024

(51) Int. Cl. G01R 19/10; G01R 33/00; G01R 33/07; G01R 33/09

(52) U.S. Cl. CPC G01R 19/10; G01R 33/0052; G01R 33/07; G01R 33/093; G01R 33/096; G01R 33/098

(57) ABSTRACT

Systems, structures, packages, circuits, and methods provide magnetic current sensors with redundant magnetic field elements or groups of elements used for current sensing. Such systems, structures, packages, circuits, and methods allow for the measurement of a diagnostic channel to be similar in amplitude to the measurement of the main channel in the case of gradient magnetic fields. Some embodiments can utilize three magnetic sensing elements or groups of elements to provide redundant safety while using less area. The sensors can provide fault indications when comparisons between the measurements made for the main and diagnostic channels are outside of a specified range or do not compare favorably.

### BACKGROUND

Magnetic field sensors can be used in a variety of applications. For example, in some applications, a magnetic field sensor can be used to detect an angle of rotation of an object. In other applications, a magnetic field sensor can be used to sense a rotation (e.g., a continuous or discontinuous rotation) of an object. Magnetic field sensors can also indirectly measure a current flowing through a conductor by measuring the magnetic field generated by the current.

Various magnetic sensing elements can be used within magnetic field sensors. For example, planar Hall effect elements and vertical Hall effect elements are known types of magnetic field sensing elements. A planar Hall effect element tends to be responsive to magnetic fields perpendicular to a surface of a substrate on which the planar Hall effect element is formed. A vertical Hall effect element tends to be responsive to magnetic fields parallel to a surface of a substrate on which the vertical Hall effect element is formed. Magnetoresistance elements are also known types of magnetic field sensing elements that are used for magnetic field sensors. Some types of magnetoresistance elements tend to be responsive to magnetic fields parallel to a surface of a substrate on which the magnetoresistance element is formed.

Various parameters characterize the performance of magnetic field sensing elements and magnetic field sensors that use magnetic field sensing elements. These parameters include sensitivity, which is a change in an output signal of a magnetic field sensing element in response to a change of magnetic field experienced by the magnetic sensing element, and linearity, which is a degree to which the output signal of the magnetic field sensing element varies in direct proportion to the magnetic field. These parameters also include an offset, which is characterized by an output signal from the magnetic field sensing element not representative of a zero magnetic field when the magnetic field sensing element experiences a zero magnetic field.

Stray magnetic fields caused by other sources such as magnetic components or electric currents can interfere with the performance of magnetic field sensors and sensing elements. Such stray magnetic fields may pose significant problems in applications, e.g., automotive, where electric motors, batteries, and other electromagnetic components are used. For example, electric motors that drive electric vehicles (“EVs”) and hybrid electric vehicles (“HEVs”) typically require significant amounts of electric current, and therefore produce strong magnetic fields around the cables delivering the electric current from the battery or alternator to the motor. Other common lower-current components can also generate significant stray magnetic fields in automotive applications, e.g., electronic power steering (“EPS”) pumps, electric windows or sunroofs, and any other electrically actuated devices used in the vehicles. Because stray magnetic fields can affect the accuracy of the magnetic fields sensors and can cause significant output errors for such sensors, systems and signal processing relying on such sensors can likewise be negatively impacted by stray magnetic fields.

### SUMMARY

Aspects of the present disclosure are directed to co-located differential magnetic field sensors, circuits/circuitry, assemblies, and related methods.

One general aspect of the present disclosure includes a differential current sensor providing safety redundancy. The differential current sensor can include: a first plurality of magnetic field sensing elements in a first region relative to a conductor and configured to detect a main magnetic field produced by current in the conductor, the first plurality of magnetic field sensing elements including, a first group of magnetic field sensing elements configured to detect the main magnetic field, where outputs of the first group are configured as a main channel for main magnetic field measurements, and a second group of magnetic field sensing elements configured to detect the main magnetic field, where outputs of the second group are configured as a redundant channel for main magnetic field measurements. The redundancy also includes a second plurality of magnetic field sensing elements in a second region relative to the conductor and configured to detect one or more stray magnetic fields, the second plurality of magnetic field sensing elements including, a third group of magnetic field sensing elements configured to detect the one or more stray magnetic fields, where outputs of the third group are configured as a main channel for stray magnetic field measurements, and a fourth group of magnetic field sensing elements configured to detect the one or more stray magnetic fields, where outputs of the fourth group are configured as a redundant channel for stray magnetic field measurements. The redundancy also includes where the sensor is configured to provide a first differential output signal based on outputs of the first and third groups of magnetic field sensing elements; where the sensor is configured to provide a second differential output signal based on the second and fourth groups of magnetic field sensing elements, and where the sensor is configured to provide a fault indication when the second differential output signal is outside a defined range. The differential current sensor may include or be included in a package, e.g., made from or including molding material. In some embodiments, the magnetic field sensing elements may be disposed on and/in a suitable substrate, e.g., a PCB, a leadframe, a ceramic substrate, etc. Other embodiments of this aspect include corresponding computer systems, apparatus, and computer programs recorded on one or more computer storage devices, each configured to perform the actions of the methods.

Implementations may include one or more of the following features. The sensor may include one or more comparators configured to perform a comparison of one or more components of the second differential output signal to one or more defined values. The one or more comparators may include one or more processors. The first group of magnetic field sensing elements may include a pair of magnetic field sensing elements; where the second group of magnetic field sensing elements may include a pair of magnetic field sensing elements; where the third group of magnetic field sensing elements may include a pair of magnetic field sensing elements; and where the fourth group of magnetic field sensing elements may include a pair of magnetic field sensing elements. The first group of magnetic field sensing elements may include four magnetic field sensing elements; where the second group of magnetic field sensing elements may include four magnetic field sensing elements; where the third group of magnetic field sensing elements may include four field sensing elements may include; and where the fourth group of magnetic field sensing elements may include four magnetic field sensing elements. The first differential output signal is based on a difference between outputs of the first and third groups of magnetic field sensors; and where the second differential output signal is based on a difference between the second and fourth groups of magnetic field sensors. The first differential output signal is based on a difference between the output signals of the first and third groups of magnetic field sensors summed with a difference between output signals of the second and fourth groups of magnetic field sensors; and where the second differential output signal is based on a difference between output signals of the second and fourth groups of magnetic field sensing elements subtracted from a difference between outputs signals of the first and third groups of magnetic field sensors. The first and second pluralities of magnetic field sensing elements may include Hall effect elements. The first and second pluralities of magnetic field sensing elements may include magnetoresistance (XMR) elements. The XMR elements may include tunneling magnetoresistance (TMR) elements. The XMR elements may include giant magnetoresistance (GMR) elements. The XMR elements may include anisotropic magnetoresistance (AMR) elements. The sensor may include a plurality of Gilbert cells (or other suitable mixers/topologies) configured to connect the outputs of the first and second pluralities of magnetic field sensing elements first and second outputs of the sensor. The plurality of Gilbert cells may include two Gilbert cells. The plurality of Gilbert cells may include four Gilbert cells.

One general aspect includes a method of making a redundant magnetic field based current sensor. The method can include: providing a first plurality of magnetic field sensing elements in a first region and configured to detect a main magnetic field produced by current in the conductor, the first plurality of magnetic field sensing elements including, a first group of magnetic field sensing elements configured to detect the main magnetic field, where outputs of the first group are configured as a main channel for main magnetic field measurements, and a second group of magnetic field sensing elements configured to detect the main magnetic field, where outputs of the second group are configured as a redundant channel for main magnetic field measurements. The method can include providing a second plurality of magnetic field sensing elements in a second region relative to the conductor and configured to detect one or more stray magnetic fields, the second plurality of magnetic field sensing elements including, a third group of magnetic field sensing elements configured to detect the one or more stray magnetic fields, where outputs of the third group are configured as a main channel for stray magnetic field measurements, and a fourth group of magnetic field sensing elements configured to detect the one or more stray magnetic fields, where outputs of the fourth group are configured as a redundant channel for stray magnetic field measurements. The sensor can be configured to provide a first differential output signal based on outputs of the first and third groups of magnetic field sensing elements; where the sensor is configured to provide a second differential output signal based on the second and fourth groups of magnetic field sensing elements, where the sensor is configured to provide a fault indication when the second differential output signal is outside a defined range. The differential current sensor may include or be included in a package, e.g., made from or including molding material. In some embodiments, the magnetic field sensing elements may be disposed on and/in a suitable substrate, e.g., a PCB, a leadframe, a ceramic substrate, etc.

Implementations may include one or more of the following features. The method may include providing one or more comparators configured to perform a comparison of one or more components of the second differential output signal to one or more defined values. The one or more comparators may include one or more processors. The first group of magnetic field sensing elements may include a pair of magnetic field sensing elements; where the second group of magnetic field sensing elements may include a pair of magnetic field sensing elements; where the third group of magnetic field sensing elements may include a pair of magnetic field sensing elements; and where the fourth group of magnetic field sensing elements may include a pair of magnetic field sensing elements. The first group of magnetic field sensing elements may include four magnetic field sensing elements; where the second group of magnetic field sensing elements may include four magnetic field sensing elements; where the third group of magnetic field sensing elements may include four field sensing elements may include; and where the fourth group of magnetic field sensing elements may include four magnetic field sensing elements. The first differential output signal can be based on a difference between outputs of the first and third groups of magnetic field sensors; and where the second differential output signal can be based on a difference between the second and fourth groups of magnetic field sensors. The first differential output signal can be based on a difference between the output signals of the first and third groups of magnetic field sensors summed with a difference between output signals of the second and fourth groups of magnetic field sensors; and where the second differential output signal can be based on a difference between output signals of the second and fourth groups of magnetic field sensing elements subtracted from a difference between outputs signals of the first and third groups of magnetic field sensors. The first and second pluralities of magnetic field sensing elements may include Hall effect elements. The first and second pluralities of magnetic field sensing elements may include magnetoresistance (XMR) elements. The XMR elements may include tunneling magnetoresistance (TMR) elements. The XMR elements may include giant magnetoresistance (GMR) elements. The XMR elements may include anisotropic magnetoresistance (AMR) elements. The method may include a plurality of Gilbert cells configured to connect the outputs of the first and second pluralities of magnetic field sensing elements first and second outputs of the sensor. The plurality of Gilbert cells may include two Gilbert cells. The plurality of Gilbert cells may include four Gilbert cells.

Another general aspect of the present disclosure includes a differential triad element current sensor. The differential triad element current sensor can include: a first set of magnetic field sensing elements in a first region relative to a conductor and configured to detect a main magnetic field produced by current in the conductor; a second set of magnetic field sensing elements in a second region relative to the conductor and configured to detect a main magnetic field produced by current in the conductor; and a third set of magnetic field sensing elements in a third region relative to the conductor and configured to detect a main magnetic field produced by current in the conductor, where the third region is between positioned along a path of the conductor between the first and second regions; where the sensor is configured to provide a first differential output signal indicative based on output signals of the first and second sets of magnetic field sensing elements; where the sensor is configured to provide a second differential output signal based on outputs signals of the third set of magnetic field sensing elements and outputs signals of the first or second sets of magnetic field sensing elements; and where the sensor is configured to provide a fault indication when a comparison of the first differential output signal to the second differential output signal is outside a defined range. The differential current sensor may include or be included in a package, e.g., made from or including molding material. In some embodiments, the magnetic field sensing elements may be disposed on and/in a suitable substrate, e.g., a PCB, a leadframe, a ceramic substrate, etc.

Implementations may include one or more of the following features. The sensor where the first, second, and third sets of magnetic field sensing elements may include one or more magnetic field sensing elements, respectively. The first, second, and third sets of magnetic field sensing elements may include Hall effect elements. The first, second, and third sets of magnetic field sensing elements may include magnetoresistance (XMR) elements. The XMR elements may include tunneling magnetoresistance (TMR) elements. The XMR elements may include giant magnetoresistance (GMR) elements. The XMR elements may include anisotropic magnetoresistance (AMR) elements.

One general aspect includes a method of making a differential triad element current sensor. The method also includes providing a first set of magnetic field sensing elements in a first region relative to a conductor and configured to detect a main magnetic field produced by current in the conductor; providing pa second set of magnetic field sensing elements in a second region relative to the conductor and configured to detect a main magnetic field produced by current in the conductor; and providing a third set of magnetic field sensing elements in a third region relative to the conductor and configured to detect a main magnetic field produced by current in the conductor, where the third region is between positioned along a path of the conductor between the first and second regions; where the sensor is configured to provide a first differential output signal indicative based on output signals of the first and second sets of magnetic field sensing elements; where the sensor is configured to provide a second differential output signal based on outputs signals of the third set of magnetic field sensing elements and outputs signals of the first or second sets of magnetic field sensing elements; and where the sensor is configured to provide a fault indication when a comparison of the first differential output signal to the second differential output signal is outside a defined range. The differential current sensor may include or be included in a package, e.g., made from or including molding material. In some embodiments, the magnetic field sensing elements may be disposed on and/in a suitable substrate, e.g., a PCB, a leadframe, a ceramic substrate, etc. Other embodiments of this aspect include corresponding computer systems, apparatus, and computer programs recorded on one or more computer storage devices, each configured to perform the actions of the methods.

Implementations may include one or more of the following features. The first, second, and third sets of magnetic field sensing elements may include one or more magnetic field sensing elements, respectively. The first, second, and third sets of magnetic field sensing elements may include Hall effect elements. The first, second, and third sets of magnetic field sensing elements may include magnetoresistance (XMR) elements. The XMR elements may include tunneling magnetoresistance (TMR) elements. The XMR elements may include giant magnetoresistance (GMR) elements. The XMR elements may include anisotropic magnetoresistance (AMR) elements.

Implementations and embodiments of the described techniques and devices may include hardware, a method or process, and/or computer software on a computer-accessible medium. The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed embodiments may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principals of the concepts described herein. Furthermore, embodiments are illustrated by way of example and not limitation in the figures, in which:

FIGS. 1A-1C are diagrams of example integrated conductor magnetic field sensors with different co-located differential magnetic sensor configurations, in accordance with the present disclosure;

FIG. 2 is a diagram showing a first example analog circuit for comparing co-located magnetic sensors, in accordance with the present disclosure;

FIG. 3 is a diagram showing a second example analog circuit for comparing co-located magnetic sensors, in accordance with the present disclosure;

FIG. 4 is a diagram showing a third example analog circuit for comparing co-located magnetic sensors, in accordance with the present disclosure;

FIG. 5 is an example differentially-sensing integrated conductor current sensor, in accordance with the present disclosure;

FIG. 6 is an example integrated conductor current sensor having a different triad with three Hall plates, in accordance with the present disclosure;

FIG. 7 is an example an example integrated conductor current sensor having a different triad with three xMR elements, in accordance with the present disclosure;

FIG. 8 is an example an example analog circuit integrated for comparing co-located magnetic sensors having a different triad, in accordance with the present disclosure;

FIG. 9 is diagram showing steps in an example method of fabricating co-located magnetic sensors, in accordance with the present disclosure; and

FIG. 10 is a diagram showing a computing system in accordance with the present disclosure.

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Safety in magnetic current sensors has typically been achieved with a redundant set of differential Hall sensors. When the redundant magnetic field sensors (e.g., Hall plates, each with multiple elements) are placed to the side of the main channel, there can be a notable difference between the signals detected by the main and redundant channel due to the field gradient from the conductor or external sources of current. This has been shown to cause the diagnostic channel to be unreliable or to operate with poor performance.

Aspects and embodiments of the present disclosure provide measurement of current (e.g., in a conductive loop) and allow for the measurement of a diagnostic channel to be similar in amplitude to the measurement of the main channel in the case of a gradient field. One or more magnetic field sensing elements used for the main and diagnostic channels are utilized to make a differential measurement of the magnetic field generated by the current flowing in the conductor (e.g., loop). By differentially combining the measurements, the effects of any ambient stray magnetic field(s) can be removed. In some embodiments, the combining (and corresponding configuration(s)/structure(s) for combining) can have or produce different results (e.g., additive or subtractive) based on the polarity (configuration) of the outputs of the magnetic field sensing element(s) (e.g., Hall effect and/or xMR).

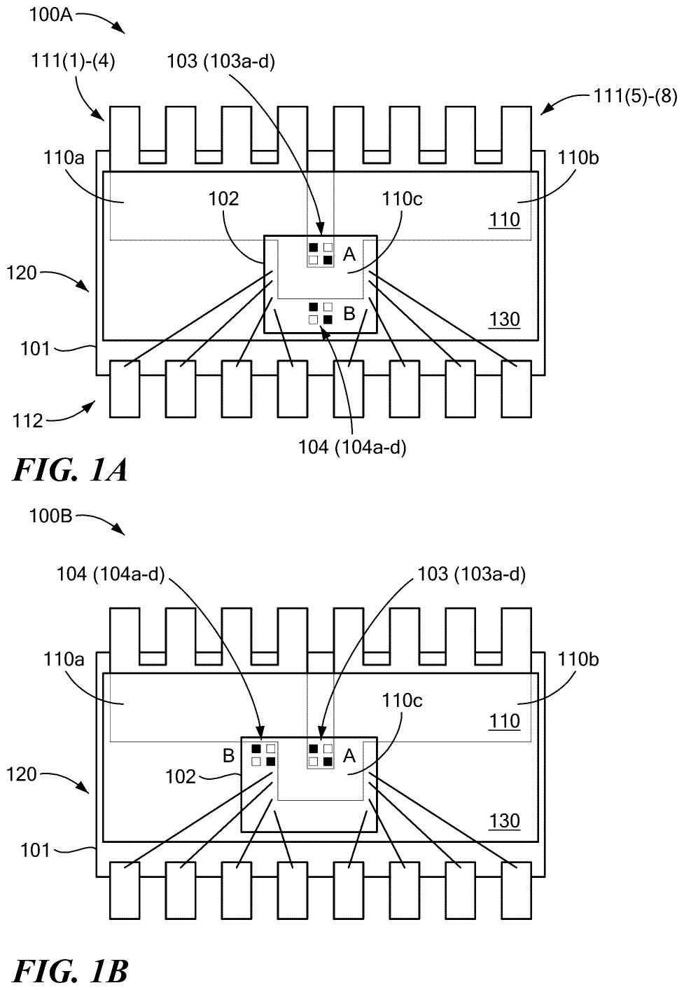

FIGS. 1A-1C are diagrams of an example integrated conductor magnetic field sensors 100A-100C with different co-located differential magnetic sensor configurations, in accordance with the present disclosure. In some embodiments sensors 100A-100C may be configured as sensor packages.

As shown in FIG. 1A, sensor configuration 100A includes a package body 101 and an integrated circuit (IC) 102 having first and second groups (pluralities) 103, 104 of magnetic field sensing elements. An integrated conductor 110 is shown having first and second ends 110a, 110b separated by a main conductive path (portion) 110c. Magnetic field element groups 103 and 104 can be located adjacent the main conductive path 110c. Sensor 100A includes groups of conductive pins 111, 112 that provide input/output functionality. As shown, pin group 111 includes first and second sub-groups 111(1)-(4) and 111(5)-(8) connected to first and second portions of integrated conductor 110. In some embodiments, first and second groups (pluralities) 103, 104 of magnetic field sensing elements may be disposed on a suitable substrate 120 within package body 101. Any suitable substrate may be used, e.g., PCB, glass, ceramic, lead frame, etc. Optional insulative/adhesive tape 130 is shown applied to package body 101. The package body 101 may be made of or include any suitable material, e.g., one or more molding materials such as epoxy molding compounds; molding compounds generally are composite materials consisting of and/or including epoxy resins, phenolic hardeners, silicas, catalysts, pigments, and mold release agents.

In some embodiments each of the first and second groups 103, 104 can include Hall effect elements, e.g., configured in or as a Hall effect plate (“Hall plate”) having four magnetic field elements. First group 103 is shown including magnetic field elements 103a-103d. In some embodiments, magnetic field elements 103a-103d can be configured as pairs of elements for main and safety channels, e.g., 103a-103b and 103c-103d, respectively. Second group 104 is shown including magnetic field elements 104a-104b. In some embodiments, magnetic field elements 103a-103d can be configured as pairs of elements for main and safety channels, e.g., 103a-103b and 103c-103d, respectively.

As shown in FIG. 1B, sensor 100B is similar to sensor 100A but utilizes an alternate position for magnetic field sensing element group 104.

As shown in FIG. 1C, sensor 100C is similar to sensors 100A-100B but utilizes alternate positions for magnetic field sensing element groups 103-104, i.e., over the main conductive path 110c of conductor 110 (as opposed to being adjacent to the path). In some embodiments, magnetic field sensing element groups 103-104 can include magnetoresistance elements (xMR), e.g., tunneling magnetoresistance elements (TMRs), giant magnetoresistance elements (GMRs), and/or anisotropic magnetoresistance elements (AMRs), etc.

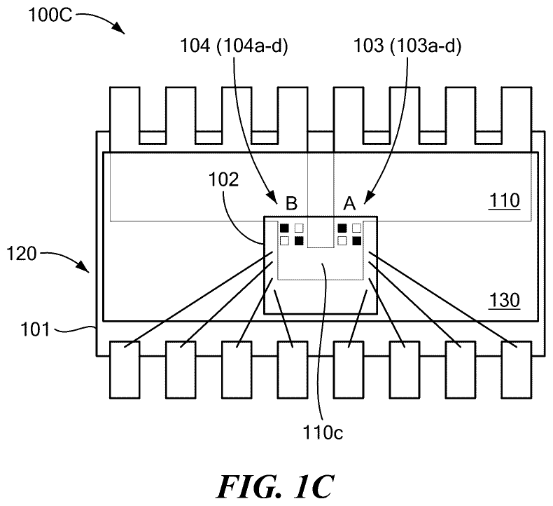

FIG. 2 is a diagram showing a first example analog circuit 200 for comparing co-located magnetic sensors, in accordance with the present disclosure. Circuit (circuitry) 200 includes first and second groups 203, 204 of magnetic field sensors. First group 203 is shown including four magnetic field sensing elements 203a-203d. In some embodiments, magnetic field elements 203a-203d can be configured as pairs of elements for a main magnetic field (Main) channel and a main magnetic field redundant or safety channel (Main_{Safety}), e.g., 203a-203b and 203c-203d, respectively. Second group 204 includes magnetic field elements 204a-204b. In some embodiments, magnetic field elements 204a-204d can be configured as pairs of elements for a stray magnetic field channel (Stray) and a stray magnetic field redundant or safety channel (Stray_{Safety}), e.g., 204a-204b and 204c-204d, respectively. In some embodiments, first and second groups 203, 204 can include Hall effect elements, e.g., a “Hall plate” having four magnetic field elements. In some embodiments, first and second groups 203, 204 can include xMR elements, e.g., four xMR elements such as TMR elements or the like.

Circuit 200 further includes four Gilbert's cells 205a-205d configured to receive outputs (output signals on output leads) from first and second groups 203, 204. First and second differential amplifiers 206a-206b receive the outputs from Gilbert's cells 205a-205b producing outputs 207a-207b. In other embodiments of the present disclosure, other suitable mixers/mixing topologies may be used instead of or addition to Gilbert cells. For non-limiting examples, in some embodiments, Jones cells, diode rings, or other mixer topologies (mixers) may be used (with suitable connections).

As indicated, output 207a is indicative of the sum of the Main and Main_{Safety} signals minus the Stray signal minus the Stray_{Safety} signals, i.e., Main+Main_{Safety}−Stray−Stray_{Safety}. Also as indicated, output 207b is indicative of the sum of the Main and Main_{Safety} signals minus the Stray signal minus the Stray_{Safety} signals, i.e., Main+Main_{Safety}−Stray−Stray_{Safety}.

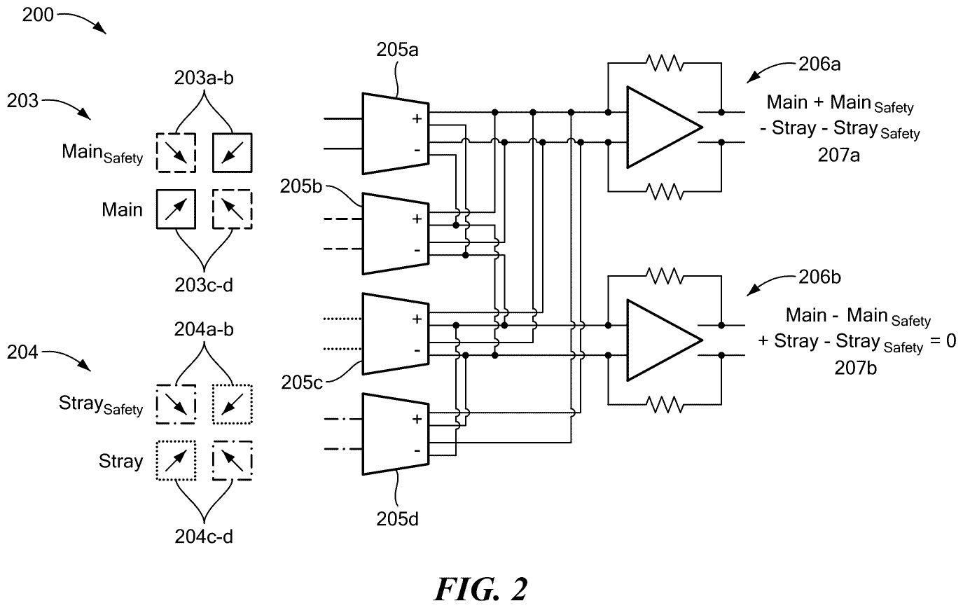

FIG. 3 is a diagram showing a second example analog circuit 300 for comparing co-located magnetic sensors, in accordance with the present disclosure. As shown, circuit (circuitry) 300 can include first and second groups 303-304 of magnetic field sensors. First group 303 is shown including magnetic field elements (field elements) 303a-303d. In some embodiments, magnetic field elements 303a-303d can be configured as pairs of elements for main magnetic field channel (Main) and a related safety or redundant channel (Main_{Safety}), e.g., 303a-303b and 303c-303d, respectively. Second group 304 is shown including magnetic field elements 304a-304d. In some embodiments, magnetic field elements 304a-304d can be configured as pairs of elements for a stray magnetic field channel (Stray) and a related safety or redundant channel (Stray_{Safety}), e.g., 304a-304b and 304c-304d, respectively. In some embodiments, first and second groups 303, 304 can include Hall effect elements, e.g., configured as or including a Hall plate having four Hall effect elements. In some embodiments, first and second groups 303, 304 can include xMR elements, e.g., four TMR elements.

Circuit 300 further includes two Gilbert cells 305a-205b configured to receive outputs (output signals on output leads/paths) from first and second groups 303, 304. First and second differential amplifiers 306a-306b receive the outputs from Gilbert cells 305a-305b producing (differential) outputs 307a-307b. As noted above, in other embodiments of the present disclosure, other suitable mixers/mixing topologies may be used instead of or addition to Gilbert cells. For non-limiting examples, in some embodiments, Jones cells or other translinear multipliers, diode rings, or other mixer topologies (mixers) may be used (with suitable connections).

As indicated, in some embodiments, output 307a can be indicative of one-half of the difference of the Main and Main_{Safety} signals plus one-half of the difference of the Stray and the Stray_{Safety} signals, i.e., 0.5 (Main−Main_{Safety})+0.5 (Stray−Stray_{Safety}). Also as indicated, in some embodiments, output 307b can be indicative of one-half of the difference of the Main and Main_{Safety} signals minus one-half of the difference of the Stray and the Stray_{Safety} signals, i.e., 0.5 (Main−Main_{Safety})−0.5(Stray−Stray_{Safety}); the combined signals for output 307b should sum to zero (0) or be close to zero for normal/correct operation of sensor 300.

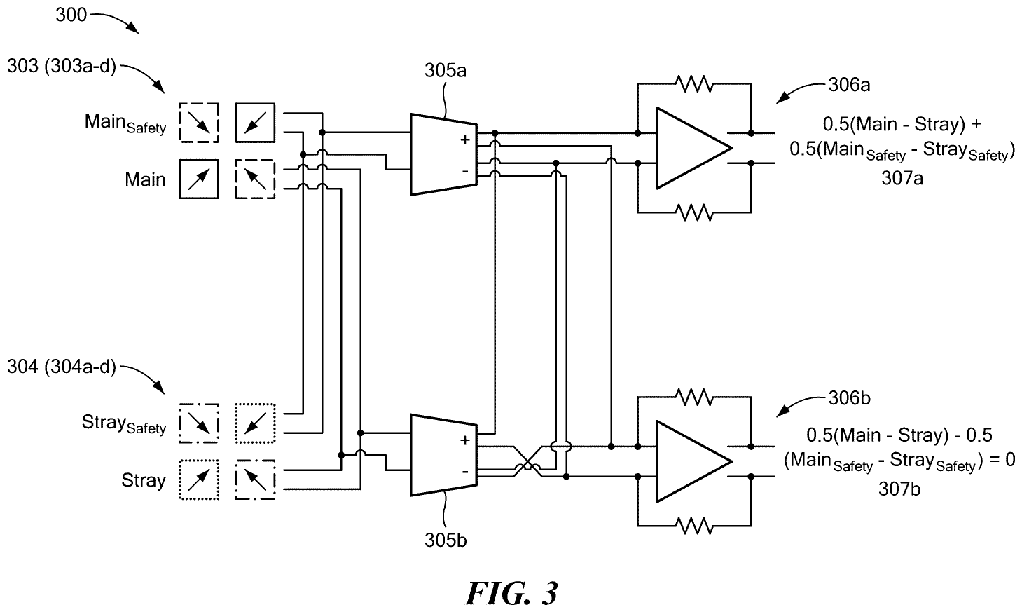

FIG. 4 is a diagram showing a third example analog circuit 400 for comparing co-located magnetic sensors, in accordance with the present disclosure. Circuit (circuitry) 400 includes first and second groups 403, 404 of magnetic field sensing elements. First group 403 is shown including magnetic field elements 403a-403d. In some embodiments, magnetic field elements 403a-403d can be configured as pairs of elements for a main magnetic field channel (Main) and a related main magnetic field safety channel (Main_{Safety}) channel, e.g., 403a-403b and 403c-403d, respectively. Second group 404 is shown including magnetic field elements 404a-404d. In some embodiments, magnetic field elements 403a-403d can be configured as pairs of elements for a stray magnetic field (Stray) and a related stray magnetic field safety channel (Stray_{Safety}), e.g., 403a-403b and 403c-403d, respectively. In some embodiments, first and second groups 403, 404 can include Hall effect elements, e.g., four Hall effect elements configured in or as a Hall plate. In some embodiments, first and second groups 403, 404 can include xMR elements, e.g., four TMR elements.

Circuit 400 further includes two Gilbert cells 405a-405b configured to receive outputs (output signals on output leads) from first and second groups 403, 404. First and second differential amplifiers 406a-406b receive the outputs from Gilbert cells 405a-405b producing outputs 407a-407b.

As indicated, in some embodiments, output 407a can be indicative of one-half of the difference of the Main and Stray signals, i.e., 0.5 (Main−Stray). In some embodiments, output 407b can be indicative of one-half of the difference of the Main_{Safety} and Stray_{Safety} signals, i.e., 0.5 (Main_{Safety}−Stray_{Safety}).

In some embodiments, a current sensor circuit can include two sets of differential Hall elements such as plate groups, placed in a specific orientations around the current-carrying loop. One plate group can be used as the Main (A) channel, and one plate group can be used as the Redundant (B) channel. Plates A & B can be positioned side-by-side for each of the differential plate groups. By measuring and comparing the differential field from channels A and B, a check can be made to determine whether the output of the Main (A) channel is correct. The Redundant (B) channel may have a signal chain which is homogeneously or heterogeneously redundant, depending on the device safety goals.

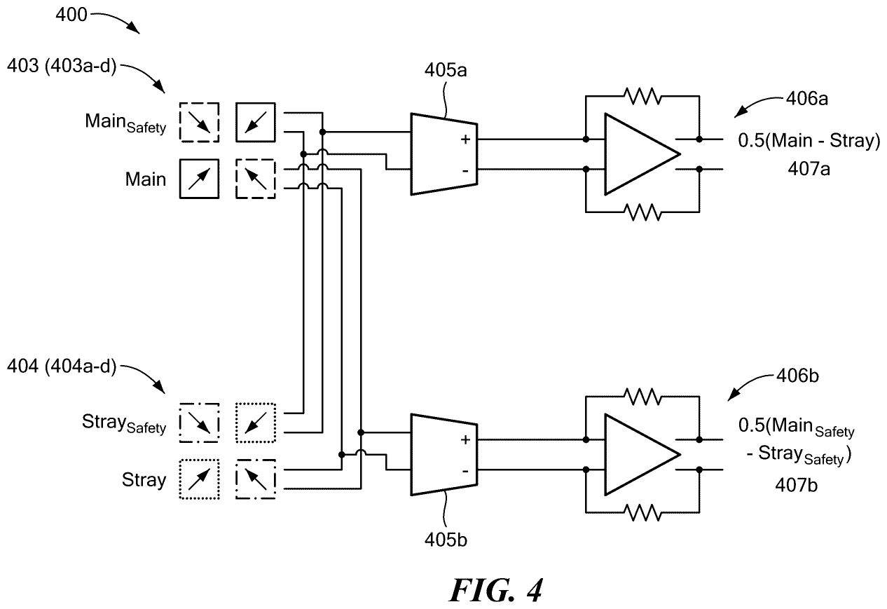

FIG. 5 is an example differentially-sensing integrated conductor current sensor 500, in accordance with the present disclosure. Sensor 500 includes a package body 501 and an integrated circuit (IC) 502 having first and second groups (pluralities) 503, 504 of magnetic field sensing elements. An integrated conductor 510 is shown having first and second ends 510a, 510b separated by a main conductive path (portion) 510c. Magnetic field element groups 103 and 104 can be located, e.g., adjacent the main conductive path 110c. Sensor 500 includes groups of conductive pins/leads 511, 512 that provide input/output functionality. In some embodiments, IC 502 may be disposed on a suitable substrate 520 within package body 501. Optional insulative/adhesive tape 530 is shown applied to package body 501.

In some embodiments each of the first and second magnetic field element groups 503, 504 can include Hall effect elements, e.g., configured in or as a Hall effect plate (“Hall plate”) having four magnetic field elements. First group 503 is shown including magnetic field elements 503a-503h configured in two sub-groups 503a-503d and 503e-503h. In some embodiments, magnetic field elements 503a-503h can be configured as quads of elements (e.g., two Hall plates) for main and main safety channels, e.g., 503a-503d and 503e-503h, respectively. Second field element group 504 is shown including magnetic field elements 504a-504h. In some embodiments, magnetic field elements 503a-503h can be configured as quads of elements (e.g., two Hall plates) for stray and stray safety channels, e.g., 504a-504d and 504e-504h, respectively. The configuration shown for groups 503 and 504 can allow for the measurement of the diagnostic channel to be similar in amplitude to the measurement of the main channel in the case of a gradient field, which is normally the case when measuring a field generated by a conductor without a concentrator core. Suitable circuitry can be used to process differential outputs from the groups 503 and 504, e.g., similar to as those shown and described for FIG. 204.

In some embodiments of the present disclosure, a current sensor circuit can include three sets of field elements (a.k.a., a “differential triad”), e.g., Hall effect elements or plate groups, placed in a specific orientations/locations around a current-carrying loop.

For example, two elements (e.g., elements A & C) can be placed to differentially sense current through a current-carrying conductor—such as through a leadframe of a package or a current-carrying trace on a PCB. A third element (e.g., element B) can be placed in between elements A and C to form a line of three points. By measuring the differential fields between A-B and B-C, comparisons can be made with the sensor differential output measurement A-B, with scaling factors included. An example is given by the following equation, where y and z are appropriate scaling factors:

$$( A - C ) = y * ( A - B ) = z * ( B - C ) \qquad ( EQ . 1 )$$

If the above calculation (in EQ. 1) falls outside of a given window, the sensor can indicate a fault in the signal path. Such a configuration can provide redundancy, e.g., for safety purposes, while requiring less area for sensor/elements.

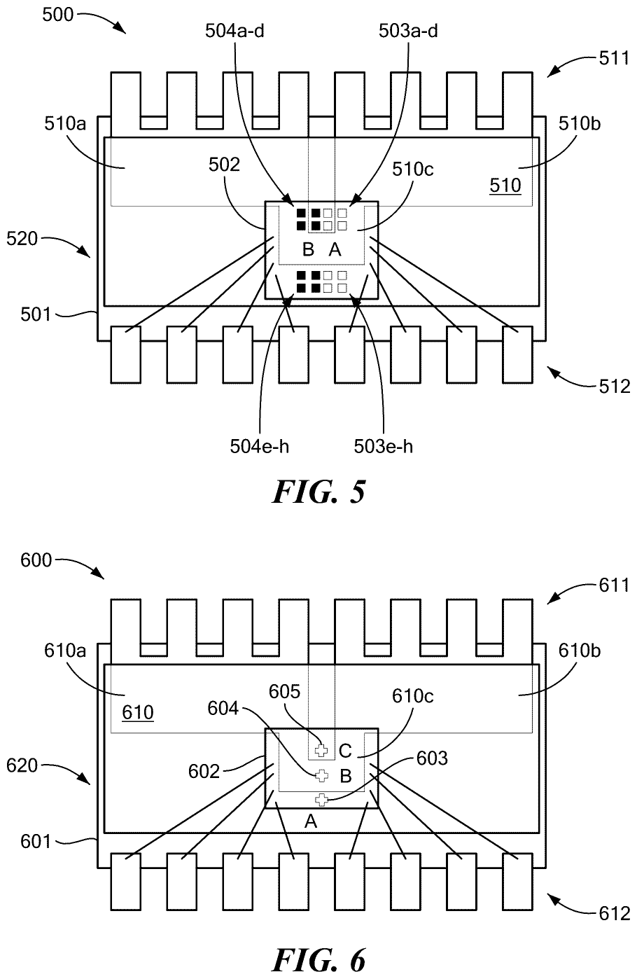

FIG. 6 is an example integrated conductor current sensor 600 having a differential triad with three Hall plates, in accordance with the present disclosure. Sensor 600 includes a package body 601 and an integrated circuit (IC) 602 having first (603), second (604), and third (605) individual magnetic field sensing elements or groups of magnetic field sensing elements. An integrated conductor 610 is shown having first and second ends 610a, 610b separated by a main conductive path (portion) 610c. Magnetic field elements or element groups 603, 604, and 604 can be located adjacent the main conductive path 610c, e.g., in locations A, B, and C, respectively, as shown. Sensor 600 includes groups of conductive pins 611, 612 that provide input/output functionality. In some embodiments, IC 602 may be disposed on a suitable substrate 620 within package body 601. Optional insulative/adhesive tape 630 is shown applied to package body 601.

As noted above, by measuring the differential fields between A-B and B-C, comparisons can be made with the sensor differential output measurement A-B, with scaling factors included, in accordance with EQ. 1. If the calculation or calculations in EQ. 1 fall/s outside of a given window, the sensor 600 can indicate a fault in the signal path. Such a configuration can provide redundancy, e.g., for safety purposes, while requiring less area for sensor/elements.

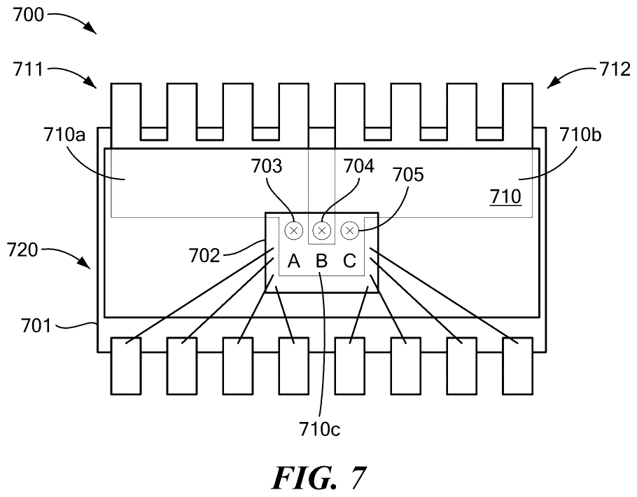

FIG. 7 is an example an example integrated conductor current sensor 700 having a differential triad with three xMR elements, in accordance with the present disclosure. Sensor 700 is generally similar to sensor 600 of FIG. 6 but instead employs xMR sensing elements.

Sensor 700 includes a package body 701 holds/contains an integrated circuit (IC) 702 having first (703), second (704), and third (705) individual magnetic field sensing elements or groups of magnetic field sensing elements. An integrated conductor 710 is shown having first and second ends 710a, 710b separated by a main conductive path (portion) 710c. Magnetic field elements or element groups 703, 704, and 704 can be located adjacent the main conductive path 710c, e.g., in locations A, B, and C, respectively, as shown. Sensor 700 includes groups of conductive pins 711, 712 that provide input/output functionality. In some embodiments, IC 702 may be disposed on a suitable substrate 720 within package body 701. Optional insulative/adhesive tape 730 is shown as applied to package body 701.

As noted above, by measuring the differential fields between A-B and B-C, comparisons can be made with the sensor differential output measurement A-B, with scaling factors included, in accordance with EQ. 1. If the calculation or calculations in EQ. 1 fall/s outside of a given window, the sensor 700 can indicate a fault in the signal path. Such a configuration can provide redundancy, e.g., for safety purposes, while requiring less area for sensor/elements.

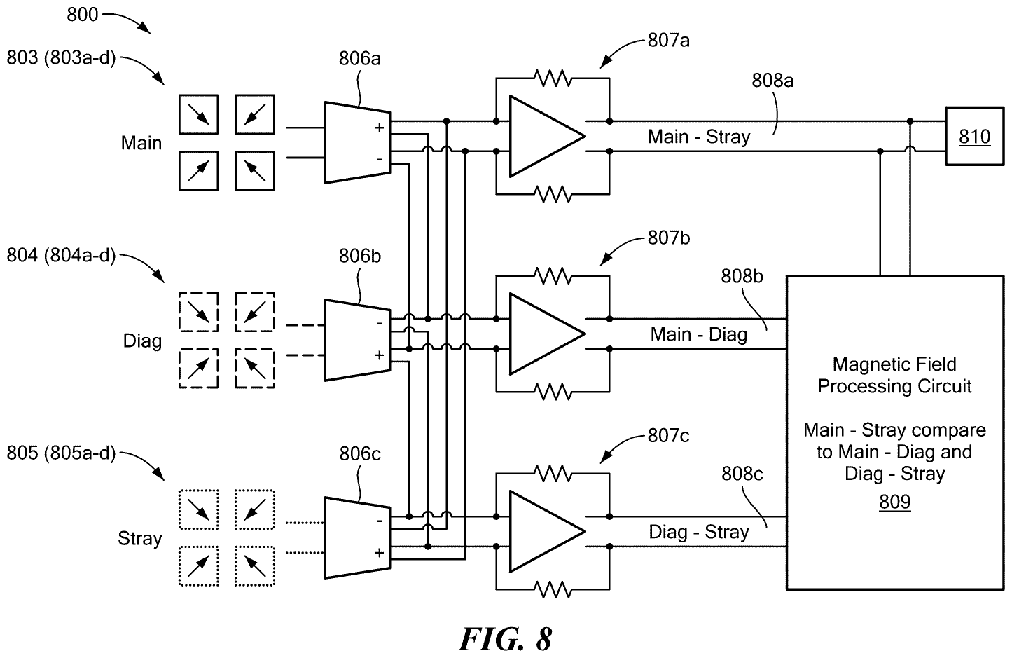

FIG. 8 is an example an example analog circuit 800 for comparing co-located magnetic sensors having a differential triad of field elements, in accordance with the present disclosure. Circuit (circuitry) 800 is shown including first, second, and third individual magnetic field sensing elements or groups of magnetic field sensing elements 803-805. In some embodiments, the field elements or groups of field elements can include Hall effect elements, e.g., individual Hall effect elements or four elements configured in or as a Hall plate. In some embodiments, first, second, and third field elements or groups 803, 804, and 805 can include XMR elements, e.g., four xMR elements such as TMR elements or the like.

Circuit 800 further includes three Gilbert cells 805a-805c configured to receive outputs (output signals on output leads) from first, second, and third individual elements or element groups 803, 804, 805. First, second, and third differential amplifiers 806a-806c receive the outputs from Gilbert cells 805a-805c producing outputs 807a-807c.

As indicated, in some embodiments, output 807a can be indicative of the difference of the Main and Stray (A-C) signals, i.e., Main-Stray; output 807b can be indictive of the difference between the Main and Diagonal (A-B) signals, i.e., Main-Diagonal; and output 807c can be indictive of the difference between the Diagonal and Stray (B-C) signals, i.e., Diagonal-Stray.

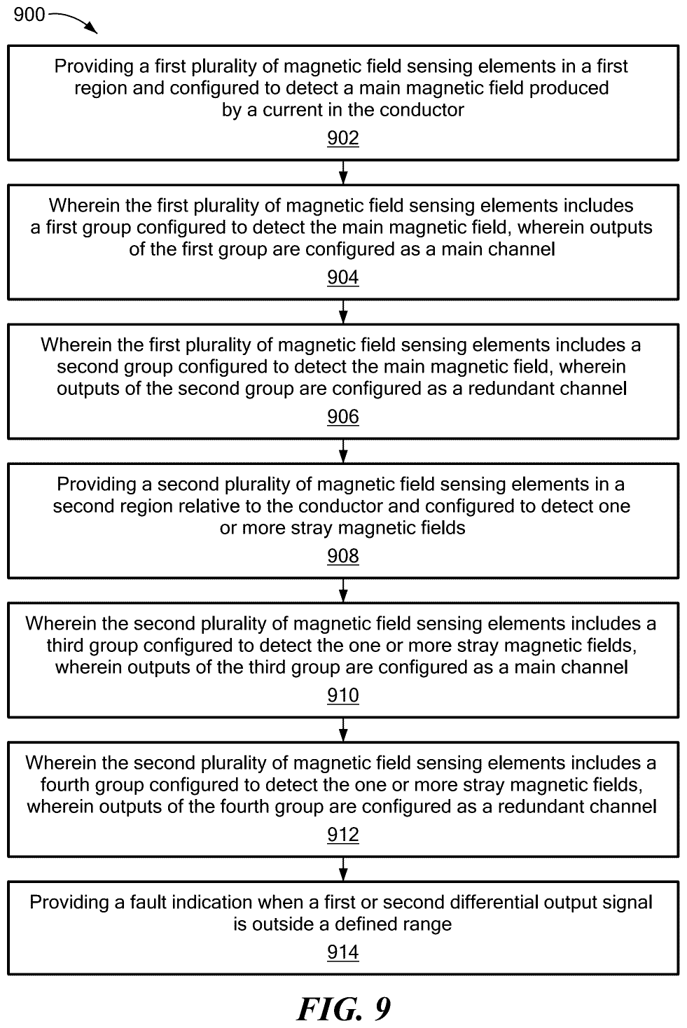

FIG. 9 is diagram showing steps in an example method 900 of fabricating co-located magnetic sensors, in accordance with the present disclosure. Method 900 can include providing a first plurality of magnetic field sensing elements in a first region and configured to detect a main magnetic field produced by current in the conductor, as described at 902. The first plurality of magnetic field sensing elements can include a first group configured to detect the main magnetic field, wherein outputs of the first group are configured as a main (Main) channel, as described at 904. The first plurality of magnetic field sensing elements can include a second group configured to detect the main magnetic field, wherein outputs of the second group are configured as a redundant or safety (Safety) channel, as described at 906.

Method 900 can include providing a second plurality of magnetic field sensing elements in a second region relative to the conductor and configured to detect one or more stray magnetic fields, as described at 908. The second plurality of magnetic field sensing elements can include a third group configured to detect the one or more stray magnetic fields, wherein outputs of the third group are configured as a main channel, as described at 910. The second plurality of magnetic field sensing elements can include a fourth group configured to detect the one or more stray magnetic fields, wherein outputs of the fourth group are configured as a redundant channel, as described at 912. Method 900 includes providing a fault indication when a first or second differential output signal is outside a defined range, as described at 914.

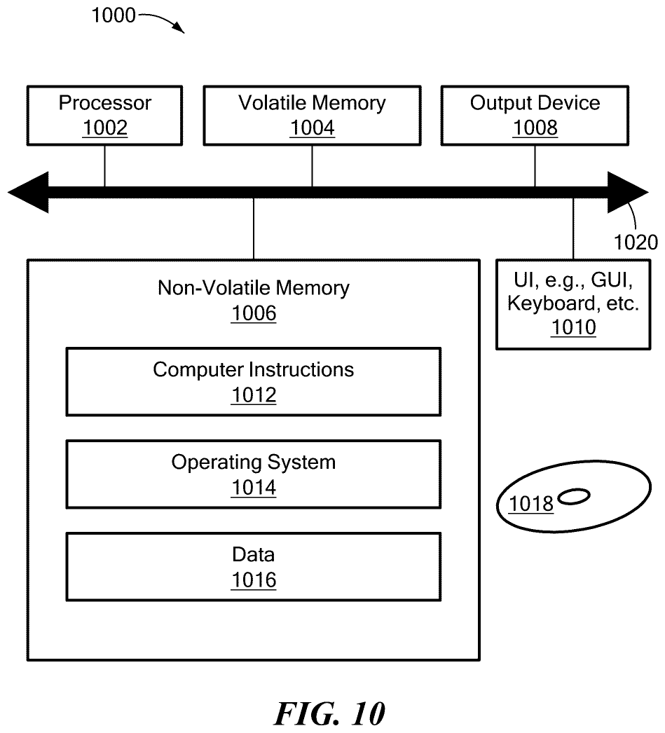

FIG. 10 is a diagram showing a computing system 1000 in accordance with the present disclosure. Computer system 1000 can perform all or at least a portion of the processing, e.g., steps in algorithms and methods, described herein, including but not limited to calculation of current based on signals from a current sensor and/or one or more magnetic field sensing elements. The computer system 1000 includes a processor 1002, a volatile memory 1004, a non-volatile memory 1006 (e.g., hard disk, etc.), an output device 1008 and a user input or interface (UI) 1010, e.g., graphical user interface (GUI), a mouse, a keyboard, a display, and/or any common user interface, etc. The non-volatile memory (non-transitory storage medium) 1006 stores computer instructions 1012 (a.k.a., machine-readable instructions or computer-readable instructions) such as software (computer program product), an operating system 1014 and data 1016. In some examples/embodiments, the computer instructions 1012 can be executed by the processor 1002 out of (from) volatile memory 1004. In some examples/embodiments, an article 1018 (e.g., a storage device or medium such as a hard disk, an optical disc, magnetic storage tape, optical storage tape, flash drive, etc.) includes or stores the non-transitory computer-readable instructions. Bus 1020 is also shown. In some embodiments, one or more components of system 1000 can be disposed on or connected to one or more integrated circuits on one or more semiconductor die.

Processing may be implemented in hardware, software, or a combination of the two. Processing may be implemented in computer programs (e.g., software applications) executed on programmable computers/machines that each includes a processor, a storage medium or other article of manufacture that is readable by the processor (including volatile and non-volatile memory and/or storage elements), and optionally at least one input device, and one or more output devices. Program code may be applied to data entered using an input device or input connection (e.g., a port or bus) to perform processing and to generate output information.

The system 1000 can perform processing, at least in part, via a computer program product or software application, (e.g., in a machine-readable storage device), for execution by, or to control the operation of, data processing apparatus (e.g., a programmable processor, a computer, or multiple computers). Each such program may be implemented in a high-level procedural or object-oriented programming language to communicate with a computer system. The programs may be implemented in assembly or machine language. The language may be a compiled or an interpreted language and it may be deployed in any form, including as a stand-alone program or as a module, component, subroutine, or other unit suitable for use in a computing environment. A computer program may be deployed to be executed on one computer or on multiple computers at one site or distributed across multiple sites and interconnected by a communication network. A computer program may be stored on a storage medium or device (e.g., CD-ROM, hard disk, or magnetic diskette) that is readable by a general or special purpose programmable computer for configuring and operating the computer when the storage medium or device is read by the computer. Processing may also be implemented as a machine-readable storage medium, configured with a computer program, where upon execution, instructions in the computer program cause the computer to operate. Further, the terms “computer” or “computer system” may include reference to plural like terms, unless expressly stated otherwise.

Processing may be performed by one or more programmable processors executing one or more computer programs to perform the functions of the system. All or part of the system may be implemented as special purpose logic circuitry, e.g., an FPGA (field programmable gate array) and/or an ASIC (application-specific integrated circuit). In some examples, digital logic circuitry, e.g., one or more FPGAs, can be operative as one or more processors as described herein.

Accordingly, embodiments and/or examples of the inventive subject matter can afford various benefits relative to prior art techniques. For example, embodiments and examples of the present disclosure can enable or facilitate diagnostic channels that provide measurements similar in amplitude to the measurement of the main channel in the case of a gradient field. Embodiments can also provide redundancy for safety while utilizing less area compared to prior art techniques.

Various embodiments of the concepts, systems, devices, structures, and techniques sought to be protected are described above with reference to the related drawings. Alternative embodiments can be devised without departing from the scope of the concepts, systems, devices, structures, and techniques described. For example, in some embodiments, other types of xMR can be used beyond TMR, GMR, and/or AMR types.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration.” Any embodiment or design described as “exemplary” is not necessarily to be construed as preferred or advantageous over other embodiments or designs. The terms “one or more” and “at least one” may indicate any integer number greater than or equal to one, i.e., one, two, three, four, etc.; those terms, however, may refer to fractional numbers/values where context admits, e.g., a number of loops in a transformer coil may be a plurality that includes a fractional value, e.g., 2.75, 3.5, 4.25, etc. The term “plurality” can refer to any integer or fractional value greater than one. The term “connection” can include an indirect connection and a direct connection.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within +20% of a target (or nominal) value in some embodiments, within plus or minus (+) 10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and implemented in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. A differential current sensor providing safety redundancy, the sensor comprising:
a first plurality of magnetic field sensing elements in a first region relative to a conductor and configured to detect a main magnetic field produced by current in the conductor, the first plurality of magnetic field sensing elements including,
a first group of magnetic field sensing elements configured to detect the main magnetic field, wherein outputs of the first group are configured as a main channel for main magnetic field measurements, and
a second group of magnetic field sensing elements configured to detect the main magnetic field, wherein outputs of the second group are configured as a redundant channel for main magnetic field measurements;
a second plurality of magnetic field sensing elements in a second region relative to the conductor and configured to detect one or more stray magnetic fields, the second plurality of magnetic field sensing elements including,
a third group of magnetic field sensing elements configured to detect the one or more stray magnetic fields, wherein outputs of the third group are configured as a main channel for stray magnetic field measurements, and
a fourth group of magnetic field sensing elements configured to detect the one or more stray magnetic fields, wherein outputs of the fourth group are configured as a redundant channel for stray magnetic field measurements;
wherein the sensor is configured to provide a first differential output signal based on outputs of the first and third groups of magnetic field sensing elements;
wherein the sensor is configured to provide a second differential output signal based on the second and fourth groups of magnetic field sensing elements; and
wherein the sensor is configured to provide a fault indication when the second differential output signal is outside a defined range.

2. The sensor of claim 1, further comprising one or more comparators configured to perform a comparison of one or more components of the second differential output signal to one or more defined values.

3. The sensor of claim 2, wherein the one or more comparators comprise one or more processors.

4. The sensor of claim 1, wherein the first group of magnetic field sensing elements comprises a pair of magnetic field sensing elements; wherein the second group of magnetic field sensing elements comprises a pair of magnetic field sensing elements;
wherein the third group of magnetic field sensing elements comprises a pair of magnetic field sensing elements; and
wherein the fourth group of magnetic field sensing elements comprises a pair of magnetic field sensing elements.

5. The sensor of claim 1, wherein the first group of magnetic field sensing elements comprises four magnetic field sensing elements;
wherein the second group of magnetic field sensing elements comprises four magnetic field sensing elements;
wherein the third group of magnetic field sensing elements comprises four field sensing elements comprises; and
wherein the fourth group of magnetic field sensing elements comprises four magnetic field sensing elements.

6. The sensor of claim 1, wherein the first differential output signal is based on a difference between outputs of the first and third groups of magnetic field sensors; and
wherein the second differential output signal is based on a difference between the second and fourth groups of magnetic field sensors.

7. The sensor of claim 1, wherein the first differential output signal is based on a difference between the output signals of the first and third groups of magnetic field sensors summed with a difference between output signals of the second and fourth groups of magnetic field sensors; and
wherein the second differential output signal is based on a difference between output signals of the second and fourth groups of magnetic field sensing elements subtracted from a difference between outputs signals of the first and third groups of magnetic field sensors.

8. The sensor of claim 1, wherein the first and second pluralities of magnetic field sensing elements comprise Hall effect elements.

9. The sensor of claim 1, wherein the first and second pluralities of magnetic field sensing elements comprise magnetoresistance (xMR) elements.

10. The sensor of claim 9, wherein the xMR elements comprise tunneling magnetoresistance (TMR) elements.

11. The sensor of claim 9, wherein the xMR elements comprise giant magnetoresistance (GMR) elements.

12. The sensor of claim 9, wherein the xMR elements comprise anisotropic magnetoresistance (AMR) elements.

13. The sensor of claim 1, further comprising a plurality of Gilbert cells configured to connect the outputs of the first and second pluralities of magnetic field sensing elements first and second outputs of the sensor.

14. The sensor of claim 9, wherein the plurality of Gilbert cells comprise two Gilbert cells.

15. The sensor of claim 9, wherein the plurality of Gilbert cells comprises four Gilbert cells.

16. A method of making a redundant magnetic field based current sensor, the method comprising:
providing a first plurality of magnetic field sensing elements in a first region and configured to detect a main magnetic field produced by current in the conductor, the first plurality of magnetic field sensing elements including,
a first group of magnetic field sensing elements configured to detect the main magnetic field, wherein outputs of the first group are configured as a main channel for main magnetic field measurements, and
a second group of magnetic field sensing elements configured to detect the main magnetic field, wherein outputs of the second group are configured as a redundant channel for main magnetic field measurements; and
providing a second plurality of magnetic field sensing elements in a second region relative to the conductor and configured to detect one or more stray magnetic fields, the second plurality of magnetic field sensing elements including,
a third group of magnetic field sensing elements configured to detect the one or more stray magnetic fields, wherein outputs of the third group are configured as a main channel for stray magnetic field measurements, and
a fourth group of magnetic field sensing elements configured to detect the one or more stray magnetic fields, wherein outputs of the fourth group are configured as a redundant channel for stray magnetic field measurements;
wherein the sensor is configured to provide a first differential output signal based on outputs of the first and third groups of magnetic field sensing elements;
wherein the sensor is configured to provide a second differential output signal based on the second and fourth groups of magnetic field sensing elements; and
wherein the sensor is configured to provide a fault indication when the second differential output signal is outside a defined range.

17. The method of claim 16, further comprising providing one or more comparators configured to perform a comparison of one or more components of the second differential output signal to one or more defined values.

18. The method of claim 17, wherein the one or more comparators comprise one or more processors.

19. The method of claim 16, wherein the first group of magnetic field sensing elements comprises a pair of magnetic field sensing elements; wherein the second group of magnetic field sensing elements comprises a pair of magnetic field sensing elements;
wherein the third group of magnetic field sensing elements comprises a pair of magnetic field sensing elements; and
wherein the fourth group of magnetic field sensing elements comprises a pair of magnetic field sensing elements.

20. The method of claim 16, wherein the first group of magnetic field sensing elements comprises four magnetic field sensing elements;
wherein the second group of magnetic field sensing elements comprises four magnetic field sensing elements;
wherein the third group of magnetic field sensing elements comprises four field sensing elements comprises; and
wherein the fourth group of magnetic field sensing elements comprises four magnetic field sensing elements.

21. The method of claim 16, wherein the first differential output signal is based on a difference between outputs of the first and third groups of magnetic field sensors; and
wherein the second differential output signal is based on a difference between the second and fourth groups of magnetic field sensors.

22. The method of claim 16, wherein the first differential output signal is based on a difference between the output signals of the first and third groups of magnetic field sensors summed with a difference between output signals of the second and fourth groups of magnetic field sensors; and
wherein the second differential output signal is based on a difference between output signals of the second and fourth groups of magnetic field sensing elements subtracted from a difference between outputs signals of the first and third groups of magnetic field sensors.

23. The method of claim 16, wherein the first and second pluralities of magnetic field sensing elements comprise Hall effect elements.

24. The method of claim 16, wherein the first and second pluralities of magnetic field sensing elements comprise magnetoresistance (xMR) elements.

25. The method of claim 24, wherein the xMR elements comprise tunneling magnetoresistance (TMR) elements.

26. The method of claim 24, wherein the xMR elements comprise giant magnetoresistance (GMR) elements.

27. The method of claim 24, wherein the xMR elements comprise anisotropic magnetoresistance (AMR) elements.

28. The method of claim 16, further comprising a plurality of Gilbert cells configured to connect the outputs of the first and second pluralities of magnetic field sensing elements first and second outputs of the sensor.

29. The method of claim 28, wherein the plurality of Gilbert cells comprise two Gilbert cells.

30. The method of claim 28, wherein the plurality of Gilbert cells comprises four Gilbert cells.

31. A differential triad element current sensor comprising:
a first set of magnetic field sensing elements in a first region relative to a conductor and configured to detect a main magnetic field produced by current in the conductor;
a second set of magnetic field sensing elements in a second region relative to the conductor and configured to detect a main magnetic field produced by current in the conductor; and
a third set of magnetic field sensing elements in a third region relative to the conductor and configured to detect a main magnetic field produced by current in the conductor, wherein the third region is between positioned along a path of the conductor between the first and second regions;
wherein the sensor is configured to provide a first differential output signal indicative based on output signals of the first and second sets of magnetic field sensing elements;
wherein the sensor is configured to provide a second differential output signal based on outputs signals of the third set of magnetic field sensing elements and outputs signals of the first or second sets of magnetic field sensing elements; and
wherein the sensor is configured to provide a fault indication when a comparison of the first differential output signal to the second differential output signal is outside a defined range.

32. The sensor of claim 31, wherein the first, second, and third sets of magnetic field sensing elements comprise one or more magnetic field sensing elements, respectively.

33. The sensor of claim 31, wherein the first, second, and third sets of magnetic field sensing elements comprise Hall effect elements.

34. The sensor of claim 31, wherein the first, second, and third sets of magnetic field sensing elements comprise magnetoresistance (xMR) elements.

35. The sensor of claim 34, wherein the xMR elements comprise tunneling magnetoresistance (TMR) elements.

36. The sensor of claim 34, wherein the xMR elements comprise giant magnetoresistance (GMR) elements.

37. The sensor of claim 34, wherein the xMR elements comprise anisotropic magnetoresistance (AMR) elements.

38. A method of making a differential triad element current sensor, the method comprising:
providing a first set of magnetic field sensing elements in a first region relative to a conductor and configured to detect a main magnetic field produced by current in the conductor;
providing pa second set of magnetic field sensing elements in a second region relative to the conductor and configured to detect a main magnetic field produced by current in the conductor; and
providing a third set of magnetic field sensing elements in a third region relative to the conductor and configured to detect a main magnetic field produced by current in the conductor, wherein the third region is between positioned along a path of the conductor between the first and second regions;
wherein the sensor is configured to provide a first differential output signal indicative based on output signals of the first and second sets of magnetic field sensing elements;
wherein the sensor is configured to provide a second differential output signal based on outputs signals of the third set of magnetic field sensing elements and outputs signals of the first or second sets of magnetic field sensing elements; and
wherein the sensor is configured to provide a fault indication when a comparison of the first differential output signal to the second differential output signal is outside a defined range.

39. The method of claim 38, wherein the first, second, and third sets of magnetic field sensing elements comprise one or more magnetic field sensing elements, respectively.

40. The method of claim 38, wherein the first, second, and third sets of magnetic field sensing elements comprise Hall effect elements.

41. The method of claim 38, wherein the first, second, and third sets of magnetic field sensing elements comprise magnetoresistance (xMR) elements.

42. The method of claim 41, wherein the xMR elements comprise tunneling magnetoresistance (TMR) elements.

43. The method of claim 41, wherein the xMR elements comprise giant magnetoresistance (GMR) elements.

44. The method of claim 41, wherein the xMR elements comprise anisotropic magnetoresistance (AMR) elements.
